(19) United States
(12) Patent Application Publication
(10) Pub. No.: US 2006/0113569 A1
(43) Pub. Date: Jun. 1, 2006

(54) Control of threshold voltage in organic field effect transistors

(76) Inventors: Akintunde I. Akinwande, Newton, MA (US); Vladimir Bulovic, Lexington, MA (US); Ioannis Kymissis, Somerville, MA (US); Annie I. Wang, Cambridge, MA (US)

Correspondence Address: Gauthier & Connors LLP, Suite 2300, 225 Franklin Street, Boston, MA, 02110, US

(21) Appl. No.: 11/266,070

(22) Filed: Nov. 3, 2005

Related U.S. Application Data
(60) Provisional application No. 60/624,586, filed on Nov. 3, 2004.

(51) Int. Cl. H01L 29/76

(52) U.S. Cl. 257/213

(57) ABSTRACT

A field effect transistor (FET) includes a substrate, and a gate layer formed on the substrate. An oxygen plasmarized polymeric gate dielectric is formed on the gate layer so as to increase the threshold voltage of the OFET. A semiconductor layer is formed on the oxygen plasmarized polymeric gate dielectric.

### PRIORITY INFORMATION

This application claims priority from provisional application Ser. No. 60/624,586 filed Nov. 3, 2004, which is incorporated herein by reference in its entirety.

### BACKGROUND OF THE INVENTION

The invention relates to the field of field effect transistors (FETs), and in particular to adjusting threshold voltage in organic FETs by introducing a layer of traps at the gate dielectric/semiconductor interface.

Significant advances have been made over the past 5 years in the field of organic field effect transistors. Improvements have been made in contact behavior, processability, mobility, on/off ratio, and a number of other figures of merit.

Virtually all high performance organic field effect transistor work is performed using pentacene as the organic semiconductor. Pentacene is a short, 5-ring aromatic molecule which sublimes in vacuum and can be deposited on substrates at or near room temperature. Holes are significantly more mobile than electrons in pentacene, and PMOS accumulation or depletion mode transistors are usually formed (depending on the threshold voltage). Most other organic semiconductors are also hole-carrying, although there are significant exceptions (e.g. fluorinated pthalalocyanines).

A major stumbling block in OFET technology has been the inability to deterministically control the threshold voltage. Management of the threshold voltage is key to optimization of device performance. In a PMOS device, a threshold voltage which is too positive requires multi-level logic and power supplies to make regenerating logic gates, and too negative of a V_{T} requires a large voltage swing (and consequently more power) to operate. The converse is true for an NMOS device.

### SUMMARY OF THE INVENTION

According to one aspect of the invention, there is provided a field effect transistor (FET). The FET includes a substrate and a gate layer formed on the substrate. An oxygen plasmarized polymeric gate dielectric is formed on the gate layer so as to increase the threshold voltage of the FET. A semiconductor layer is formed on the oxygen plasmarized polymeric gate dielectric.

According to another aspect of the invention, there is provided a method of forming field effect transistor (FET). The FET includes providing a substrate. A gate layer is formed on the substrate. An oxygen plasmarized polymeric gate dielectric is formed on the gate layer so as to increase the threshold voltage of the FET. The method includes forming a semiconductor layer on the oxygen plasmarized polymeric gate dielectric.

### BRIEF DESCRIPTION OF THE DRAWINGS

FIGS. 1A-1E illustrate the steps of forming the inventive OFET structure;

FIGS. 2A-2B illustrate the I-V characteristics for a standard OFET device and the inventive O₂ treated device;

FIG. 3 illustrates the quasistatic C-V curve for a standard OFET device and the inventive O₂ treated device;

FIGS. 4A-4B illustrate the extrapolated threshold voltages for a standard OFET device and the inventive O₂ treated device;

FIG. 5 illustrates the I-V characteristics of a standard OFET device and the inventive O₂ treated device in the dark under 3400 cd/m² incandescent white light illumination; and

FIG. 6 illustrates the photocurrent spectral response of a standard OFET device and the inventive O₂ treated device.

### DETAILED DESCRIPTION OF THE INVENTION

The invention comprises a three step process, which helps manage the threshold voltage of OFETs. In pentacene OFETs, this can be summarized in the following manner: (1) use a polymer gate dielectric for the OFET; (2) use an oxygen-containing plasma to dope the semiconductor with holes and move the threshold voltage more positive; and (3) apply cyclo-hexane to the organic gate dielectric surface to satisfy dangling bonds and move the threshold voltage of the finished device more negative.

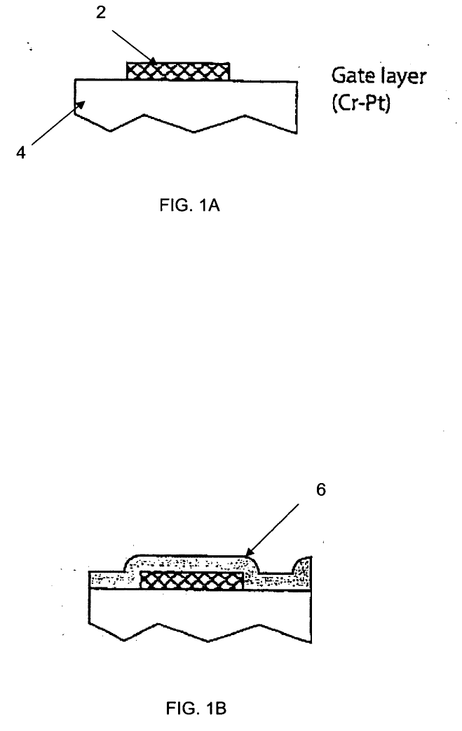

FIGS. 1A-1E illustrate the steps of forming the inventive OFET structure. FIG. 1A shows a gate layer 2 that is first deposited and patterned on an insulating substrate 4. The gate layer 2 can include a blanket gate layer, such as a conducting silicon piece, or a blanket layer of metal, but for circuit applications a patterned gate is generally required. FIG. 1B shows a polymeric gate dielectric 6 is then deposited. Parylene-C is the preferred gate dielectric material, however other similar materials can be used. FIG. 1C shows the polymeric gate dielectric 6 is then modified to adjust the trap density at the surface. An oxygen (O₂) plasma is used to increases the trap density, which tends to move the threshold voltage more positive, and a reactive passivating treatment, such as immersion in cyclohexane, tends to satisfy dangling bonds and move the threshold voltage more negative. FIG. 1D demonstrates a semiconductor layer 8 being formed on the treated gate dielectric 10. In this embodiment of the invention, the semiconductor layer 8 comprises pentacene, however other similar materials can be used. FIG 1E shows a source/drain layers 12 being formed using Au, however other similar materials can be used to form the source/drain layers.

OFETs are often modeled using conventional semiconductor device equations. More refined models have been developed to include the contributions of trap states at the semiconductor/dielectric interface by modeling them as a gate voltage dependent mobility or as localized band-gap states. The contribution of process-induced, traps in the FET linear region can be modeled as a fixed charge, Q_{fixed}, that shifts V_{T} and mobile charge, Q_{mobile,} that adds parasitic bulk conductivity. One can assume a constant mobility and model the interface states as electron acceptors.

The following model assumes a parallel conduction mechanism comprising of (a) a surface channel in which the carrier density in the surface accumulation layer is modulated by gate voltage and (b) a “bulk” layer away from the surface channel whose mobile carrier density is not modulated by the gate voltage. Fixed charge shifts the threshold voltage, V_{T}, such that V_{Tmeasured}=V_{T}−Q_{fixed}/Cᵢₙₛ where Cᵢₙₛ=insulator capacitance. Mobile charge Q_{mobile} adds parasitic bulk conductivity, i.e. ΔI_{D}=W/L*μV_{DS}*Q_{mobile}. The overall current equation for an OFET in the linear region becomes

$$- {I}_{D} = \frac{W}{L} μ {V}_{DS} [ {C}_{ins} ( {V}_{GS} - ( {V}_{T} - {Q}_{fixed} / {C}_{ins} ) ) ] + \frac{W}{L} μ {V}_{DS} {Q}_{mobile} \qquad Eq . 1$$

where W=width of the OFET, L=length, μ=field effect mobility, V_{GS}=gate to source voltage, and V_{DS}=drain to source voltage. The additional fixed charge ΔQ_{fixed} in treated devices compared to untreated devices can be calculated from the difference in measured V_{T}:
ΔQ_{fixed}=ΔV_{T}*Cᵢₙₛ Eq. 2

Although only the relative difference in Q_{fixed} can be calculated, values for Q_{mobile} can be determined for both treated and untreated devices. Since the measured values of V_{T} include the contribution of Q_{fixed}, Q_{mobile} can be solved for after differentiating equation (1) with respect to V_{DS}:

$$- {Q}_{mobile} = ( {V}_{GS} - {V}_{Tmeasured} ) {C}_{ins} + \frac{\partial ( {I}_{D} ) / ( {V}_{DS} )}{μ W / L} \qquad Eq . 3$$

For the O₂ plasma treated devices, Cᵢₙₛ=1.5×10⁻⁸ F/cm² and the change in fixed charge ΔQ_{fixed}=2.0×10⁻⁶ C/cm². The corresponding Q_{mobile}=1.1×10⁻⁶ C/cm^{2,} an order of magnitude greater than Q_{mobile}=1.1×10⁻⁷ C/cm² in the control device. Extracted values for Q_{mobile} in the O₂ treated device show that the parasitic conductivity is independent of gate voltage and on the same order of magnitude as ΔQ_{fixed}.

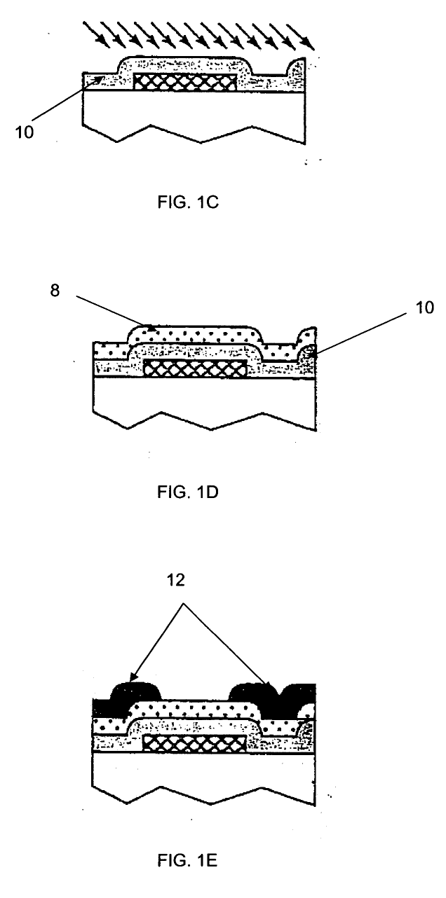

FIGS. 2A-2B illustrate the I-V characteristics for a standard OFET device and the inventive O₂ treated device. The inventive O₂ treated device has significantly more positive threshold voltage V_{T} and shows a much higher drain current than the standard OFET device.

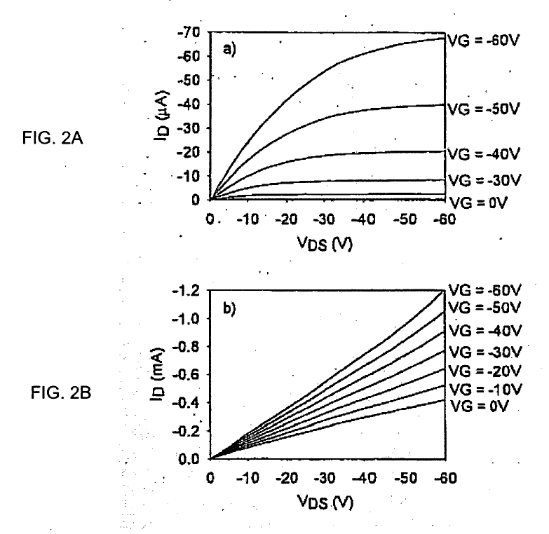

FIG. 3 illustrates the quasi-static C-V curve for a standard OFET device and the inventive O₂ treated device. The standard OFET device is in accumulation for negative gate voltages and enters depletion for positive V_{GS}. The inventive O₂ treated device remains in accumulation throughout the measurement range and does not reach flatband.

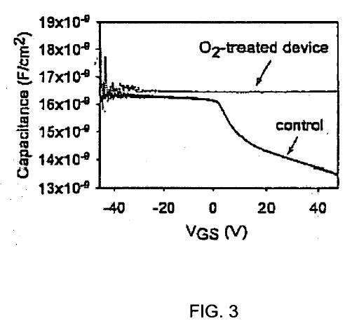

FIGS. 4A-4B illustrate the extrapolated threshold voltages for a standard OFET device and the inventive O₂ treated device. For the standard OFET device, V_{T} is extracted from saturation region measurements. Because the inventive O₂ treated device does not saturate and drain voltage (I_{D}) is high, the V_{T} is extrapolated from V_{GS} close to V_{T} to minimize contact resistance effects. The threshold voltage has been shifted.

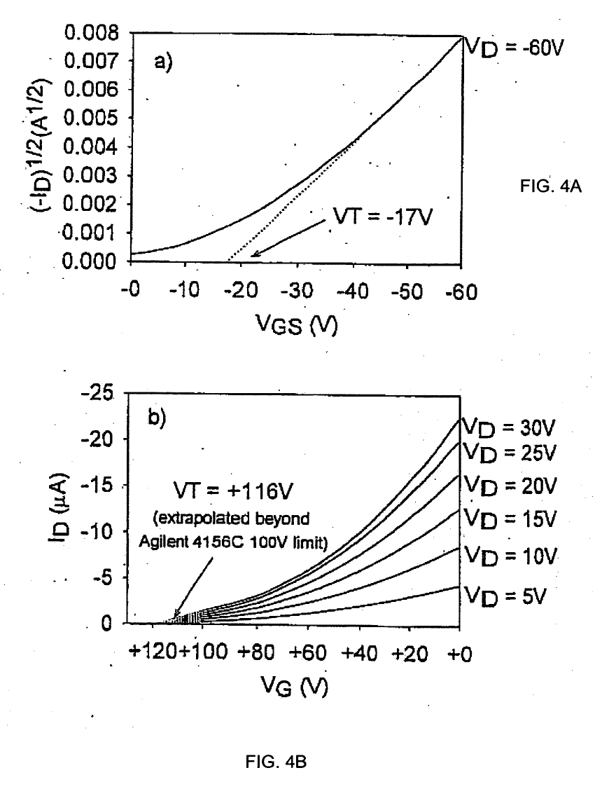

The interface states are observable in photocurrent measurements, as suggested by the enhanced photosentivity plasma treated devices, as shown in FIG. 5. Optical characterization of fully fabricated OFETs was conducted to probe the nature of interface traps. This technique probes only the interface layers of pentacene that participate in FET operation. In the nondestructive in situ measurement, monochromatic chopped light illuminated the device. The gate and drain were biased at −20V, and the current output was measured by a lock-in amplifier at the chopping frequency.

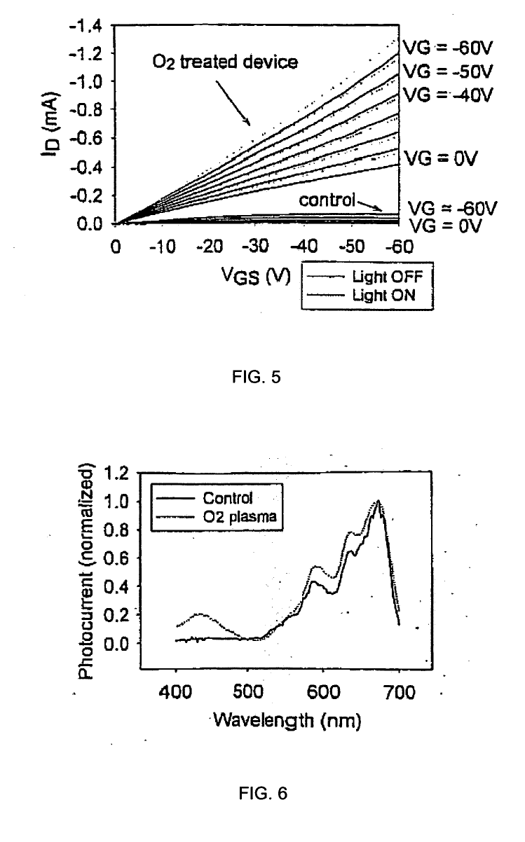

FIG. 6 shows a broad spectrum photoresponse for the control and O₂ plasma treated devices. The O₂ treated device shows an additional peak around 420 nm (3.0 eV), which corresponds to an energy transition larger than pentacene HOMO-LUMO gap of 2.1 eV. Since these trap states cannot be accessed by moving the Fermi level, these states are seen as a fixed charge. This illustrates that traps induce fixed charge that shifts the threshold voltage.

The invention demonstrates that the threshold voltage can be adjusted in organic devices by introducing a layer of traps at the gate dielectric/semiconductor interface. This operates by generating a fixed charge right next to the accumulation region of the transistor. One can also reverse this effect by saturating the dangling bonds using cyclo-hexane. When using an organic dielectric, this layer of dangling bonds can be introduced by exposing the dielectric to an oxygen containing plasma.

Organic field effect transistors (OFETs) are candidates for application in large area, flexible, and/or inexpensive circuit applications. A major challenge in the development of OFET technology has been a lack a technique to control of the threshold voltage. This invention describes such a technique. A set of process steps are developed which allows control of the threshold voltage through management of traps at the semiconductor/gate dielectric interface. These traps can be created or eliminated through two chemical treatments which are described herein. These treatments allow the placement of fixed charges at the semiconductor/gate dielectric interface, allowing control of the OFET's threshold voltage. This control is key to the design and creation of useful circuitry.

This procedure can likely be extended to other organic semiconductors, gate dielectric materials, and stacks of organic materials. Other oxidizing and reducing treatments, such as exposure with hydrogen peroxide or ozone to oxidize, or hydrogen plasma to reduce, are likely to also help shift the threshold voltage.

Although the present invention has been shown and described with respect to several preferred embodiments thereof, various changes, omissions and additions to the form and detail thereof, may be made therein, without departing from the spirit and scope of the invention.

What is claimed is:

1. A field effect transistor (FET) comprising:
a substrate;
a gate layer that is formed on said substrate;
an oxidized polymeric gate dielectric that is formed on said gate layer so as to increase the threshold voltage of said FET; and
a semiconductor layer that is formed on said oxidized polymeric gate dielectric gate dielectric.

2. The FET of claim 1, wherein said at least one drain/source layer comprises gold (Au).

3. The FET of claim 1, wherein said gate layer comprises a conducting silicon piece.

4. The FET of claim 1, wherein said gate layer comprises a blanket layer of metal.

5. The FET of claim 1, wherein said gate layer comprises a patterned gate layer.

6. The FET of claim 1, wherein said semiconductor layer comprises pentacene.

7. The FET of claim 1 further comprising at least one drain/source layer that is formed on said semiconductor layer.

8. The FET of claim 1, wherein said oxidized polymeric gate dielectric is formed using an oxygen plasma.

9. The FET of claim 1, wherein said oxidized polymeric gate dielectric is formed using an ozone treatment.

10. The FET of claim 1, wherein said semiconductor layer comprises an electron carrying material.

11. The FET of claim 1, wherein said oxidized polymeric gate dielectric comprises parylene.

12. The FET of claim 1, wherein said semiconductor layer comprises an inorganic thin film.

13. The FET of claim 1, wherein said semiconductor layer comprises an organic thin film.

14. A method of forming a field effect transistor (FET) comprising:
providing a substrate;
forming a gate layer on said substrate;
forming an oxygen plasmarized polymeric gate dielectric on said gate layer so as to increase the threshold voltage of said FET;
forming a semiconductor layer on said oxygen plasmarized polymeric gate dielectric; and
forming at least one drain/source layer on said semiconductor layer.

15. The method of claim 14, wherein said at least one drain/source layer comprises gold (Au).

16. The method of claim 14, wherein said gate layer comprises a conducting silicon piece.

17. The method of claim 14, wherein said gate layer comprises a blanket layer of metal.

18. The method of claim 14, wherein said gate layer comprises a patterned gate layer.

19. The method of claim 14, wherein said semiconductor layer comprises pentacene.

20. The method of claim 1 further comprising forming at least one drain/source layer on said semiconductor layer.

21. The method of claim 14, wherein said oxidized polymeric gate dielectric is formed using an oxygen plasma.

22. The method of claim 14, wherein said oxidized polymeric gate dielectric is formed using an ozone treatment.

23. The method of claim 14, wherein said semiconductor layer comprises an electron carrying material.

24. The method of claim 14, wherein said oxidized polymeric gate dielectric comprises parylene.

25. The method of claim 14, wherein said semiconductor layer comprises an inorganic thin film.

26. The method of claim 14, wherein said semiconductor layer comprises an organic thin film.
